(19) United States
(12) Patent Application Publication
(10) Pub. No.: US 2015/0160307 A1
(43) Pub. Date: Jun. 11, 2015

(54) ORTHOGONAL FLUXGATE SENSOR

(71) Applicant: SAMSUNG ELECTRO-MECHANICS CO., LTD., Suwon-Si (KR)

(72) Inventors: Dae Ho KIM, Suwon-Si (KR); Eun Tae Park, Suwon-Si (KR)

(73) Assignee: SAMSUNG ELECTRO-MECHANICS CO., LTD., Suwon-Si (KR)

(21) Appl. No.: 14/218,474

(22) Filed: Mar. 18, 2014

(30) Foreign Application Priority Data
Dec. 9, 2013 (KR) 10-2013-0152367

(51) Int. Cl. G01R 33/04; G01R 33/00

(52) U.S. Cl. CPC G01R 33/04; G01R 33/0005

(57) ABSTRACT

There is provided an orthogonal fluxgate sensor including: a plurality of magnetic cores each formed to be elongated in a length direction; a first coil enclosing the plurality of magnetic cores in a solenoid form; and a second coil surrounding the plurality of magnetic cores and the first coil, wherein when an alternating current (AC) power source is connected to the first coil, an AC voltmeter is connected to the second coil, and when the AC power source is connected to the second coil, the AC voltmeter is connected to the first coil.

### CROSS-REFERENCE TO RELATED APPLICATION

This application claims the benefit of Korean Patent Application No. 10-2013-0152367 filed on Dec. 9, 2013, with the Korean Intellectual Property Office, the disclosure of which is incorporated herein by reference.

### BACKGROUND

The present disclosure relates to an orthogonal fluxgate sensor.

A fluxgate sensor is a type of magnetic field sensor measuring a magnitude of a relatively weak external magnetic field by utilizing large permeability of a ferromagnetic material that is easily saturated in a magnetic field.

A fluxgate sensor has been extensively utilized as a sensor for precisely measuring a geo-magnetic field in spaceship and artificial satellites to measure a magnetic field in celestial bodies and space.

In addition, a fluxgate sensor may also be used as an electronic compass of portable electronic devices such as a smartphone, a navigation device, and the like.

An electronic compass of portable electronic devices senses a geo-magnetic field and provides information regarding a direction of a smartphone, a navigation device, and the like, providing a method of overcoming shortcomings of a global positioning system (GPS)-based location tracking.

Currently, a magnetoresistive (MR) sensor, a magnetoimage (MI) sensor, a resonator sensor based on Lorentz force, and a hall sensor, implementing low-cost production and low-power driving, while satisfying demand for precision and resolution, are typical geomagnetic sensors applied to electronic compasses of most portable electronic devices.

Current development of such sensors are directed toward improvement of more precise resolution and effective initialization performance to meet new demand for augmented reality, game controllers, indoor navigation devices, and the like, in line with the development of increasingly diversified applications.

A fluxgate sensor supports excellent resolution and effective initialization performance, and thus, if such a fluxgate sensor is miniaturized and driven with low power, it may be widely utilized in portable electronic devices, and the like.

### SUMMARY

An aspect of the present disclosure may provide an orthogonal fluxgate sensor significantly reduced in height and measuring a magnetic field in a direction perpendicular to a plane on which the sensor is formed.

An aspect of the present disclosure may also provide a compact orthogonal fluxgate sensor having a simple structure in which two coils alternately serve as a magnetic field generating coil and a detecting coil.

According to a first aspect of the present disclosure, an orthogonal fluxgate sensor may include: a plurality of magnetic cores provided in a length direction; a first coil enclosing the plurality of magnetic cores in a solenoid form; and a second coil surrounding the plurality of magnetic cores and the first coil, wherein when an alternating current (AC) power source is connected to the first coil, an AC voltmeter is connected to the second coil, and when the AC power source is connected to the second coil, the AC voltmeter is connected to the first coil.

Each of the magnetic cores may be formed to be narrow in a width direction thereof, relative to length and height directions thereof.

Each of the magnetic cores may have lower demagnetizing field over magnetic fields in the length and height directions thereof than those over a magnetic field in the width direction thereof.

The second coil may surround the plurality of magnetic cores and the first coil at least once in a spiral manner.

Each of the magnetic cores may be disposed to slope in the width direction thereof based on the height direction thereof.

Each of the magnetic cores may slope in a direction opposite to the direction in which an adjacent magnetic core slopes.

According to a second aspect of the present disclosure, an orthogonal fluxgate sensor may include: a plurality of magnetic cores provided in a length direction; a first coil disposed above or below the plurality of magnetic cores and having a spiral shape with the parts of the first coil directly above or below the magnetic cores forming parallel lines; and a second coil surrounding the plurality of magnetic cores and the first coil, wherein when an alternating current (AC) power source is connected to the first coil, an AC voltmeter is connected to the second coil, and when the AC power source is connected to the second coil, the AC voltmeter is connected to the first coil.

Each of the magnetic cores may be formed to be narrow in a width direction thereof, relative to length and height directions thereof.

Each of the magnetic cores may have lower demagnetizing field over magnetic fields in the length and height directions thereof than those over a magnetic field in the width direction thereof.

Each of the magnetic cores may be disposed to slope in the width direction thereof based on the height direction thereof.

Each of the magnetic cores may slope in a direction opposite to the direction in which an adjacent magnetic core slopes.

According to a third aspect of the present disclosure, an orthogonal fluxgate sensor may include: a first substrate having a plurality of magnetic cores formed therein; and second and third substrates stacked above and below the first substrate, wherein a first coil is formed in the second and third substrates to enclose the plurality of magnetic cores in a solenoid form, a second coil is formed in the second or third substrate to surround the plurality of magnetic cores and the first coil, and when an alternating current (AC) power source is connected to the first coil, an AC voltmeter is connected to the second coil, and when the AC power source is connected to the second coil, the AC voltmeter is connected to the first coil.

A plurality of through holes penetrating through the first substrate in a rectangular shape may be formed in the first substrate, and magnetic thin films may be provided on inner walls of the respective through holes to form the plurality of magnetic cores.

Each of the magnetic cores may have lower demagnetizing field over magnetic fields in the length and height directions thereof than those over a magnetic field in the width direction thereof.

The second coil may surround the plurality of magnetic cores and the first coil at least once in a spiral manner.

The second and third substrates may have conductive patterns formed therein, and the first through third substrates may have via holes to allow end portions of the respective conductive patterns to be connected therethrough to form the first coil in a solenoid form.

According to a fourth aspect of the present disclosure, an orthogonal fluxgate sensor may include: a first substrate having a plurality of magnetic cores formed therein; and second and third substrates stacked above and below the first substrate, wherein a first coil is formed in any one of the second and third substrates having a spiral shape with the parts of the first coil directly above or below the magnetic cores forming parallel lines; a second coil is formed in the other of the second and third substrate to surround the plurality of magnetic cores and the first coil, and when an alternating current (AC) power source is connected to the first coil, an AC voltmeter is connected to the second coil, and when An AC power source is connected to the second coil, the AC voltmeter is connected to the first coil.

A plurality of through holes penetrating through the first substrate in a rectangular shape may be formed in the first substrate, and magnetic thin films may be provided on inner walls of the respective through holes to form the plurality of magnetic cores.

Each of the magnetic cores may have lower demagnetizing field over magnetic fields in the length and height directions thereof than those over a magnetic field in the width direction thereof.

The magnetic cores may be positioned within a region of the first coil in which a current flows in the same direction.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating an orthogonal fluxgate sensor according to a first exemplary embodiment of the present disclosure;

FIG. 2 is a view schematically illustrating a modified example of a magnetic core of the orthogonal fluxgate sensor according to the first exemplary embodiment of the present disclosure;

FIG. 3A is a view schematically illustrating an orthogonal fluxgate sensor according to a second exemplary embodiment of the present disclosure;

FIG. 3B is a plan view illustrating a position of a magnetic core in the orthogonal fluxgate sensor according to the second exemplary embodiment of the present disclosure;

FIG. 4 is a view schematically illustrating a modified example of the magnetic core of the orthogonal fluxgate sensor according to the second exemplary embodiment of the present disclosure;

FIG. 5 is an exploded perspective view schematically illustrating an orthogonal fluxgate sensor according to a third exemplary embodiment of the present disclosure; and

FIG. 6 is an exploded perspective view schematically illustrating an orthogonal fluxgate sensor according to a fourth exemplary embodiment of the present disclosure.

### DETAILED DESCRIPTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

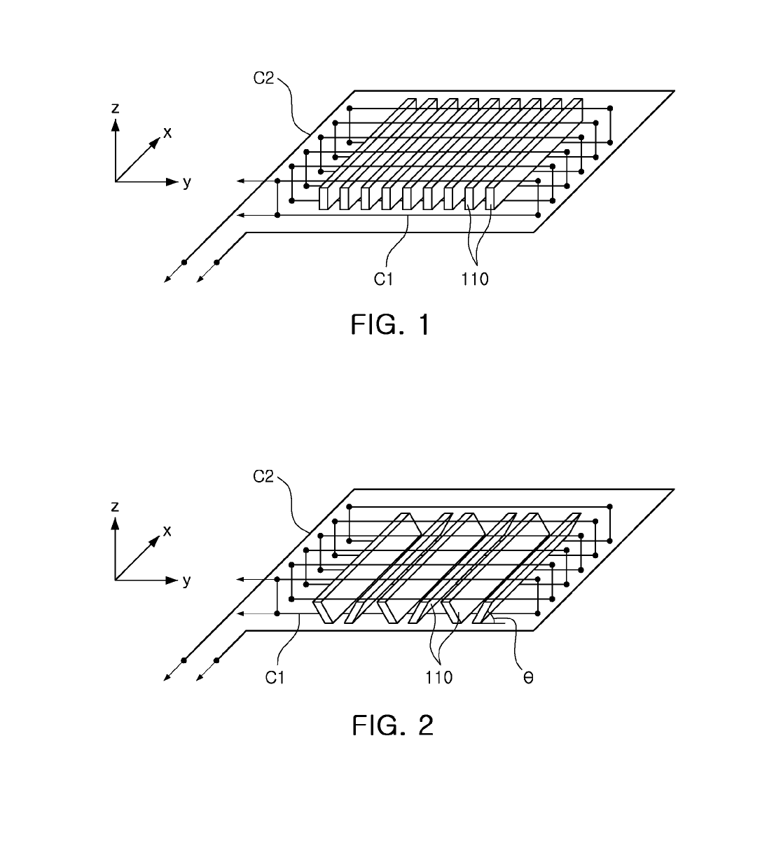

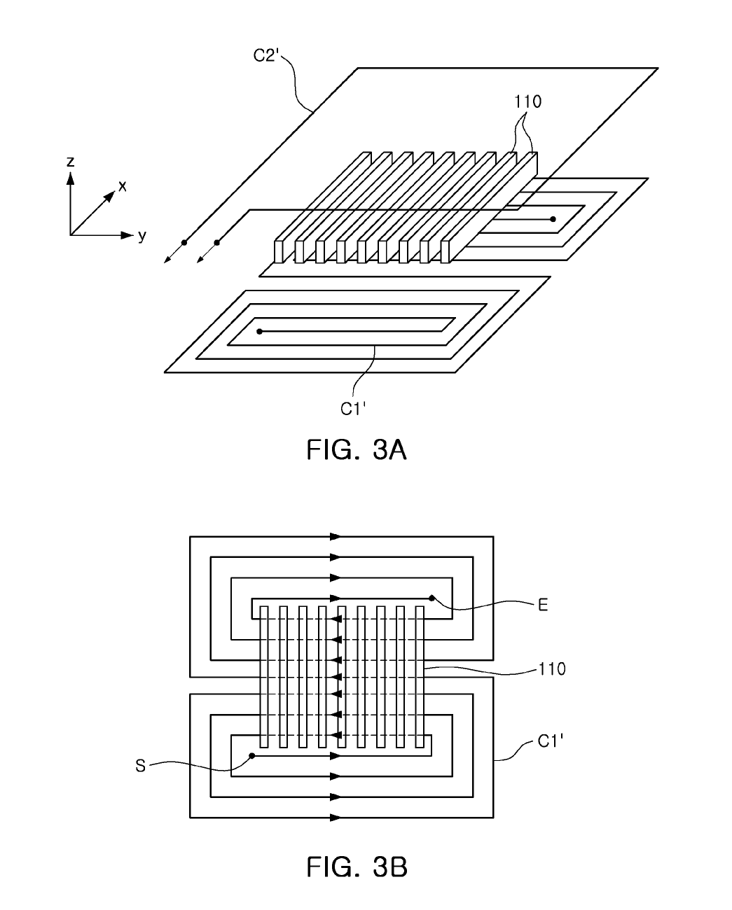

FIG. 1 is a perspective view schematically illustrating an orthogonal fluxgate sensor according to a first exemplary embodiment of the present disclosure, and FIG. 2 is a view schematically illustrating a modified example of a magnetic core of the orthogonal fluxgate sensor according to the first exemplary embodiment of the present disclosure.

Referring to FIG. 1, an orthogonal fluxgate sensor according to the first exemplary embodiment of the present disclosure may include a plurality of magnetic cores 110, a first coil C1 enclosing the plurality of magnetic cores 110 in a solenoid form, and a second coil C2 surrounding the plurality of magnetic cores 110 and the first coil C1.

The plurality of magnetic cores 110 may each have a bar shape, and may be formed to elongate in a length direction (x-axis direction).

Each of the magnetic cores 110 may be disposed to be parallel to one another.

The plurality of magnetic cores 110 may be soft magnets having small residual magnetization and high permeability, and may be formed of spinel-type ferrite, an amorphous alloy, and the like.

The plurality of magnetic cores 110 may be magnetized when an external magnetic field is applied thereto, and may be demagnetized when the applied external magnetic field is removed.

Each of the magnetic cores 110 may be formed to be narrower in a width direction (y-axis direction) thereof than in a length direction (x-axis direction) and a height direction (z-axis direction) thereof.

Namely, each of the magnetic cores 110 may have a narrow, elongated bar shape erected vertically.

Thus, each of the magnetic cores 110 may have lower demagnetizing field over magnetic fields in the length direction (x-axis direction) and the height direction (z-axis direction) than those over a magnetic field in the width direction (y-axis direction) thereof.

The plurality of magnetic cores 110 may be readily magnetized by the magnetic field in the x-axis direction induced by the first coil C1 or the magnetic field in the z-axis direction induced by the second coil C2.

Meanwhile, referring to FIG. 2, each of the magnetic cores 110 may be disposed to slope in the width direction (y-axis direction) thereof based on the height direction (z-axis direction) thereof.

Also, each of the magnetic cores 110 may slope in a direction opposite to the direction in which adjacent magnetic cores 110 slope.

Each of the magnetic cores 110 may slope to form a predetermined angle θ with respect to the x-y plane, and here, the angle θ may be greater than 30° and smaller than 90°.

In the case in which the magnetic cores 110 are disposed in this manner, each of the magnetic cores 110 may be weakly magnetized in the z-axis direction over the external magnetic field in the y-axis direction. However, since the adjacent magnetic cores 110 of the magnetic cores slope in the opposite direction, magnetization of each of the magnetic cores 110 in the z-axis direction taking place due to the external magnetic field in the y-axis direction is canceled out, eliminating the potential for the problem.

The first coil C1 may be provided to enclose the plurality of magnetic cores 110 in a solenoid form, and the second coil C2 may be provided to surround the plurality of magnetic cores 110 and the first coil C1.

In detail, the second coil C2 may surround the magnetic cores 110 and the first coil C1 on the plane on which the magnetic cores 110 are formed.

Also, the second coil C2 may surround the plurality of magnetic cores 110 and the first coil C1 in a spiral manner at least once on the x-y plane.

The first and second coils C1 and C2 may be magnetic field generating coils generating a magnetic field to magnetize the magnetic cores 110 upon receiving an alternating current (AC) applied thereto, or may be detecting coils measuring an induction voltage due to a change in magnetic moment of the magnetic cores 110 caused by an external magnetic field.

Namely, in the orthogonal fluxgate sensor according to the first exemplary embodiment, when at least one of the first and second coils C1 and C2 serves as a magnetic field generating coil, the other may serve as a detecting coil.

To this end, in a case in which an AC power source is connected to the first coil C1, an AC voltmeter may be connected to the second coil C2, and in a case in which the AC power source is connected to the second coil C2, the AC voltmeter may be connected to the first coil C1.

Thus, the first and second coils C1 and C2 may alternately serve to generate a magnetic field and detect a change in magnetic flux.

For example, in a case in which an AC power source is connected to the first coil C1 to generate a magnetic field, a voltage induced to the second coil C2 due to a change in magnetic moment of the plurality of magnetic cores 110 may be measured, and in a case in which an AC power source is connected to the second coil C2 to generate a magnetic field, a voltage induced to the first coil C1 due to a change in magnetic moment of the plurality of magnetic cores 110 may be measured.

The orthogonal fluxgate sensor according to the first exemplary embodiment of the present disclosure may operate as follows.

A method of measuring an external magnetic field (geo-magnetic field) in the z-axis direction will be described with reference to FIG. 1.

When an external magnetic field in the z-axis direction is applied, the plurality of magnetic cores 110 has magnetic moment proportional to the external magnetic field in the z-axis direction.

Here, a current is applied to the first coil C1 to apply a magnetic field in the x-axis direction to the plurality of magnetic cores 110.

Namely, in the orthogonal fluxgate sensor according to the first exemplary embodiment of the present disclosure, the direction (here, the z-axis direction) of the external magnetic field intended to be measured and the direction (here, the x-axis direction) of the magnetic field generated by the magnetic field generating coil (here, the first coil C1) to magnetize the plurality of magnetic cores 110 form a right angle.

The current applied to the first coil C1 is an AC, so the direction of the magnetic field thereof is repeatedly changing between a positive (+) direction and a negative (−) direction of the x axis.

When an instantaneous current value of the AC applied to the first coil C1 is 0, the magnetic moment of the plurality of magnetic cores 110 is maintained at the initial value (with its component only along z-axis).

When the instantaneous current value of the AC applied to the first coil C1 has a maximum positive value, the magnetic moment of the plurality of magnetic cores 110 is saturated to the x-axis direction, and thus, the initial component along the z-axis is rapidly reduced.

Here, the component along the z-axis of the magnetic moment of the plurality of magnetic cores 110 is changed, and a change in magnetic flux corresponding thereto may be sensed by the second coil C2.

Each time the instantaneous current value of the AC applied to the first coil C1 is changing between 0 and the maximum value thereof, the magnetic moment of the plurality of magnetic cores 110 in the z-axis direction is changed and may be measured by the voltage induced to the second coil C2.

The measured voltage of the second coil C2 is proportional to the magnitude of the external magnetic field in the z-axis direction.

Namely, the external magnetic field in the z-axis direction may be detected by measuring the voltage induced to the second coil C2.

Here, the first coil C1 to which the an AC power source is connected may serve as a magnetic field generating coil, and the second coil C2 connected to the AC voltmeter may serve as a detecting coil.

Hereinafter, a method of measuring an external magnetic field (geo-magnetic field) in the x-axis direction will be described.

When an external magnetic field in the x-axis direction is applied, the plurality of magnetic cores 110 have magnetic moment proportional to the external magnetic field in the x-axis direction.

Here, a current is applied to the second coil C2 to apply a magnetic field in the z-axis direction to the plurality of magnetic cores 110.

Namely, in the orthogonal fluxgate sensor according to the first exemplary embodiment of the present disclosure, the direction (here, the x-axis direction) of the external magnetic field intended to be measured and the direction (here, the z-axis direction) of the magnetic field generated by the magnetic field generating coil (here, the second coil C2) to magnetize the plurality of magnetic cores 110 form a right angle.

The current applied to the second coil C2 is an AC, so the direction of the magnetic field thereof is repeatedly changing between a positive (+) direction and a negative (−) direction of the z axis.

When an instantaneous current value of the AC applied to the second coil C2 is 0, the magnetic moment of the plurality of magnetic cores 110 is maintained at the initial value (with its component only along the x-axis).

When the instantaneous current value of the AC applied to the second coil C2 has a maximum positive value, the magnetic moment of the plurality of magnetic cores 110 is saturated to the z-axis direction, and thus, the initial component along the z-axis is rapidly reduced.

Here, the component along the x-axis of the magnetic moment of the plurality of magnetic cores 110 is changed, and a change in magnetic flux corresponding thereto may be sensed by the first coil C1.

Each time the instantaneous current value of the AC applied to the second coil C2 is changing between 0 and the maximum value thereof, the magnetic moment of the plurality of magnetic cores 110 in the x-axis direction is changed and may be measured by the voltage induced to the first coil C1.

The measured voltage of the first coil C1 is proportional to the magnitude of the external magnetic field in the x-axis direction.

Namely, the external magnetic field in the x-axis direction may be detected by measuring the voltage induced to the first coil C1.

Here, the second coil C2 to which the an AC power source is connected may serve as a magnetic field generating coil, and the first coil C1 connected to the AC voltmeter may serve as a detecting coil.

In the orthogonal fluxgate sensor according to the first exemplary embodiment of the present disclosure, since the first and second coils C1 and C2 alternately serve as a magnetic field generating coil and a detecting coil, eliminating the need for a separate magnetic field generating coil and a detecting coil, the overall size of the sensor may be reduced.

Also, since the plurality of magnetic cores 110 each formed to have a width smaller than a length and a height thereof are used, demagnetizing field of the magnetic cores 110 with respect to the magnetic fields in the length direction (the x-axis direction) and the height direction (the z-axis direction) may be reduced, improving sensitivity and efficiency of the sensor.

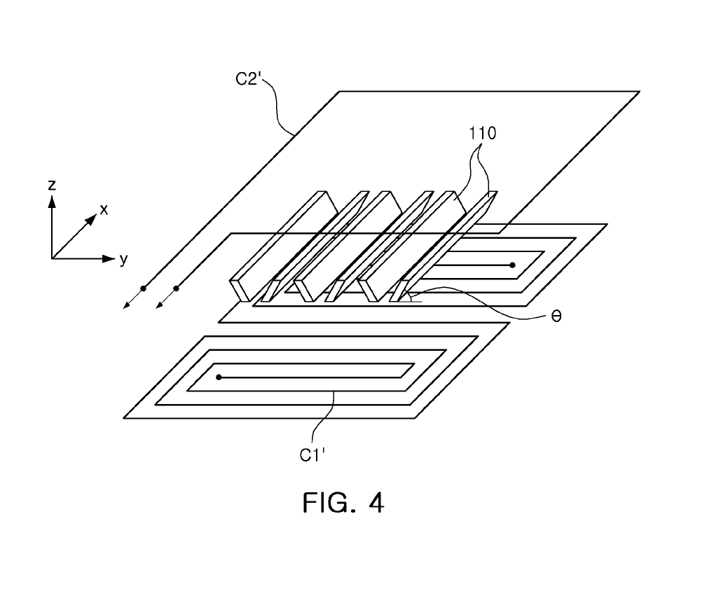

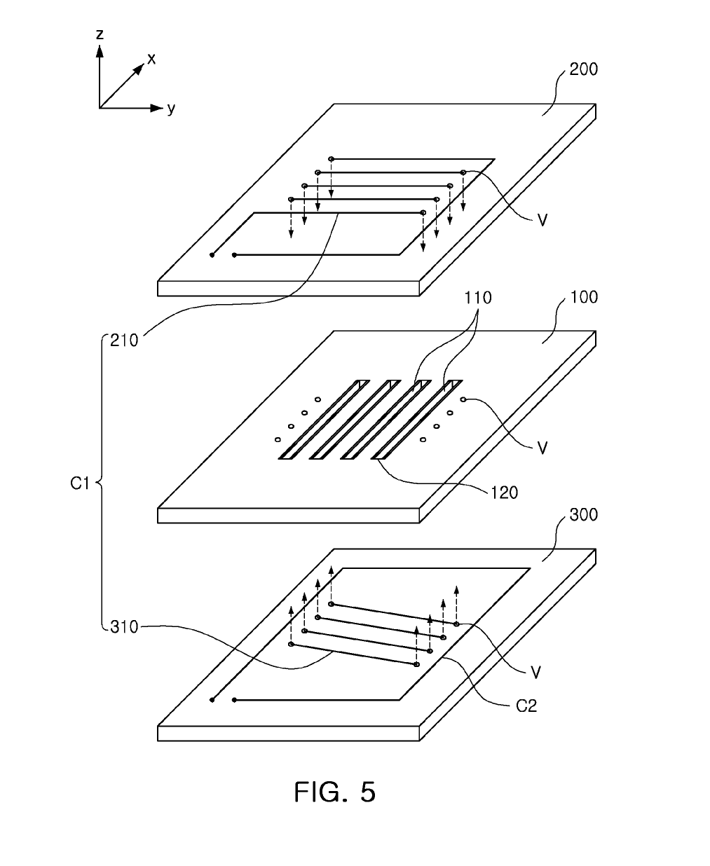

FIG. 3A is a view schematically illustrating an orthogonal fluxgate sensor according to a second exemplary embodiment of the present disclosure, FIG. 3B is a plane view illustrating a position of a magnetic core in the orthogonal fluxgate sensor according to the second exemplary embodiment of the present disclosure, and FIG. 4 is a view schematically illustrating a modified example of the magnetic core of the orthogonal fluxgate sensor according to the second exemplary embodiment of the present disclosure.

Referring to FIG. 3A, the orthogonal fluxgate sensor according to the second exemplary embodiment of the present disclosure is identical to the orthogonal fluxgate sensor according to the first exemplary embodiment of the present disclosure as described above, except for first and second coils C1′ and C2′. Thus, descriptions thereof, excluding those of the first and second coils C1′ and C2′, will be omitted.

The first coil C1′ may be disposed above or below the magnetic core 110 and may have a spiral shape with the parts of the first coil directly above or below the magnetic cores forming parallel lines.

Meanwhile, the second coil C2′ may be provided to surround the plurality of magnetic cores 110 and the first coil C1′.

In detail, the second coil C2′ may surround the magnetic cores 110 and the first coil C1′ on the plane on which the magnetic cores 110 are formed.

Further, the second coil C2′ may surround the plurality of magnetic cores 110 and the first coil C1′ at least once in a spiral manner on the x-y plane.

The first coil C1′ may be formed by connecting the outermost coil strands of two coils wound in the same direction.

Also, the first coil C1′ may be spread, while being wound in one direction, and be rewound in the opposite direction.

In other words, the first coil C1′ may have a dual-spiral structure.

Thus, as illustrated in FIG. 3B, when it is assumed that a current flows from a start point S to an end point E of the first coil C1′, in an inner portion of the first coil C1′, the current flows in the same direction.

Here, the plurality of magnetic cores 110 may be positioned within the region of the first coil C1′ in which the current flows in the same direction.

Also, the plurality of magnetic cores 110 may be positioned between the start point S and the endpoint E of the first coil C1′.

Thus, a magnetic field may be applied to the entirety of the plurality of magnetic cores 110 in a predetermined direction by the first coil C1′.

FIG. 5 is an exploded perspective view schematically illustrating an orthogonal fluxgate sensor according to a third exemplary embodiment of the present disclosure.

Referring to FIG. 5, the orthogonal fluxgate sensor according to the third exemplary embodiment of the present disclosure may include a first substrate 100 in which a plurality of magnetic cores 110 are formed, and second and third substrates 200 and 300 in which conductive patterns 210 and 310 are formed.

The second and third substrates 200 and 300 may be stacked above and below the first substrate 100 with the first substrate 100 as a center, forming a multi-layer substrate.

The plurality of magnetic cores 110 may be formed in the first substrate 100.

A plurality of through holes 120 having a rectangular shape may be formed in the first substrate 100 such that they penetrate through the first substrate 100, and in this case, magnetic thin films may be provided on inner walls of the respective through holes 120 to form the plurality of magnetic cores 110.

Namely, the plurality of magnetic cores 110 may be formed by depositing magnetic thin films on the inner walls of the through holes 120 by utilizing a thin film deposition method such as physical vapor deposition, chemical deposition, electro-deposition, and the like.

Each of the through holes 120 may be formed to be parallel to one another, and the magnetic thin films provided on the inner walls of the through holes 120 may also be parallel to one another.

The plurality of magnetic cores 110 may be soft magnets having small residual magnetization and high permeability, and may be formed of spinel-type ferrite, an amorphous alloy, and the like.

The plurality of magnetic cores 110 may be magnetized when an external magnetic field is applied thereto, and demagnetized when the applied external magnetic field is removed.

Each of the magnetic cores 110 may be formed to be narrow in the width direction (y-axis direction) thereof, relative to the length direction (x-axis direction) and the height direction (z-axis direction) thereof.

Namely, each of the magnetic cores 110 may have a narrow, elongated bar shape erected vertically.

Thus, each of the magnetic cores 110 may have lower demagnetizing field over magnetic fields in the length direction (x-axis direction) thereof and the height direction (z-axis direction) than those over the magnetic field in the width direction (y-axis direction) thereof.

The plurality of magnetic cores 110 may be readily magnetized by the magnetic field in the x-axis direction induced by the first coil C1 and the magnetic field in the z-axis direction induced by the second coil C2.

The second substrate 200 may be stacked on the first substrate 100 and the third substrate 300 may be stacked below the first substrate 100.

Conductive patterns 210 and 310 may be formed in the second and third substrates 200 and 300, and each of the conductive patterns 210 and 310 may be electrically connected by via holes V formed in the first to third substrate 100 to 300.

End portions of the conductive patterns 210 and 310 formed in the second and third substrates 200 and 300 may be connected by the via holes V to enclose the magnetic cores 110 in a solenoid form.

For example, the conductive patterns 210 and 310 formed in the second and third substrates 200 and 300 may be connected by the via holes V to configure the first coil C1 enclosing the plurality of magnetic cores 110 in a solenoid form.

The second coil C2 surrounding the plurality of magnetic cores 110 and the first coil C1 may be formed in the second or third substrate 200 or 300.

In detail, the second coil C2 may surround the magnetic cores 110 and the first coil C1 on the plane on which the magnetic cores 110 are formed.

Also, the second coil C2 may surround the plurality of magnetic cores 110 and the first coil C1 in a spiral manner at least once on the x-y plane.

The first and second coils C1 and C2 may be magnetic field generating coils generating a magnetic field to magnetize the magnetic cores 110 upon receiving an alternating current (AC) applied thereto, or may be detecting coils measuring an induction voltage according to a change in magnetic moment of the magnetic cores 110 caused by an external magnetic field.

Namely, in the orthogonal fluxgate sensor according to the third exemplary embodiment, when at least one of the first and second coils C1 and C2 serves as a magnetic field generating coil, the other may serve as a detecting coil.

To this end, in a case in which an AC power source is connected to the first coil C1, an AC voltmeter may be connected to the second coil C2, and in a case in which the AC power source is connected to the second coil C2, the AC voltmeter may be connected to the first coil C1.

Thus, the first and second coils C1 and C2 may alternately serve to generate a magnetic field and detect a change in magnetic flux.

For example, in a case in which an AC power source is connected to the first coil C1 to generate a magnetic field, a voltage induced to the second coil C2 due to a change in magnetic moment of the plurality of magnetic cores 110 may be measured, and in a case in which the AC power source is connected to the second coil C2 to generate a magnetic field, a voltage induced to the first coil C1 due to a change in magnetic moment of the plurality of magnetic cores 110 may be measured.

The orthogonal fluxgate sensor according to the third exemplary embodiment of the present disclosure may operate as follows.

A method of measuring an external magnetic field (geo-magnetic field) in the z-axis direction will be described with reference to FIG. 5.

When an external magnetic field in the z-axis direction is applied, the plurality of magnetic cores 110 has magnetic moment proportional to the external magnetic field in the z-axis direction.

Here, a current is applied to the first coil C1 to apply a magnetic field in the x-axis direction to the plurality of magnetic cores 110.

Namely, in the orthogonal fluxgate sensor according to the third exemplary embodiment of the present disclosure, the direction (here, the z-axis direction) of the external magnetic field intended to be measured and the direction (here, the x-axis direction) of the magnetic field generated by the magnetic field generating coil (here, the first coil C1) to magnetize the plurality of magnetic cores 110 form a right angle.

The current applied to the first coil C1 is an AC, so the direction of the magnetic field thereof is repeatedly changing between a positive (+) direction and a negative (−) direction of the x axis.

When an instantaneous current value of the AC applied to the first coil C1 is 0, the magnetic moment of the plurality of magnetic cores 110 is maintained at the initial value (with its component only along z-axis).

When the instantaneous current value of the AC applied to the first coil C1 has a maximum positive value, the magnetic moment of the plurality of magnetic cores 110 is saturated to the x-axis direction, and thus, the initial component along the z-axis is rapidly reduced.

Here, the component along the z-axis of the magnetic moment of the plurality of magnetic cores 110 is changed, and a change in magnetic flux corresponding thereto may be sensed by the second coil C2.

Each time the instantaneous current value of the AC applied to the first coil C1 is changing between 0 and the maximum value thereof, the magnetic moment of the plurality of magnetic cores 110 in the z-axis direction is changed and may be measured by the voltage induced to the second coil C2.

The measured voltage of the second coil C2 is proportional to the magnitude of the external magnetic field in the z-axis direction.

Namely, the external magnetic field in the z-axis direction may be detected by measuring the voltage induced to the second coil C2.

Here, the first coil C1 to which the an AC power source is connected may serve as a magnetic field generating coil, and the second coil C2 connected to the AC voltmeter may serve as a detecting coil.

Hereinafter, a method of measuring an external magnetic field (geo-magnetic field) in the x-axis direction will be described.

When an external magnetic field in the x-axis direction is applied, the plurality of magnetic cores 110 have magnetic moment proportional to the external magnetic field in the x-axis direction.

Here, a current is applied to the second coil C2 to apply a magnetic field in the z-axis direction to the plurality of magnetic cores 110.

Namely, in the orthogonal fluxgate sensor according to the third exemplary embodiment of the present disclosure, the direction (here, the x-axis direction) of the external magnetic field intended to be measured and the direction (here, the z-axis direction) of the magnetic field generated by the magnetic field generating coil (here, the second coil C2) to magnetize the plurality of magnetic cores 110 form a right angle.

The current applied to the second coil C2 is an AC, so the direction of the magnetic field thereof is repeatedly changing between a positive (+) direction and a negative (−) direction of the z axis.

When an instantaneous current value of the AC current applied to the second coil C2 is 0, the magnetic moment of the plurality of magnetic cores 110 is maintained at the initial value (x-axis directional value).

When the instantaneous current value of the AC current applied to the second coil C2 has a maximum positive value, the magnetic moment of the plurality of magnetic cores 110 is saturated in the z-axis direction, and thus, the initial z-axis directional component is rapidly reduced.

Here, the x-axis directional component of the magnetic moment of the plurality of magnetic cores 110 is changed, and a change in magnetic flux corresponding thereto may be sensed by using the first coil C1.

Each time the instantaneous current value of the AC current applied to the second coil C2 is changing between 0 and the maximum value thereof, the magnetic moment of the plurality of magnetic cores 110 in the x-axis direction is changed and may be measured by using a voltage induced to the first coil C1.

The measured voltage of the first coil C1 is proportional to a magnitude of the external magnetic field in the x-axis direction.

Namely, the external magnetic field in the x-axis direction may be detected by measuring the voltage induced to the first coil C1.

Here, the second coil C2 to which the an AC power source is connected may serve as a magnetic field generating coil, and the first coil C1 connected to the AC voltmeter may serve as a detecting coil.

In the orthogonal fluxgate sensor according to the third exemplary embodiment of the present disclosure, since the first and second coils C1 and C2 alternately serve as a magnetic field generating coil and a detecting coil, eliminating the need for a separate magnetic field generating coil and a detecting coil, the overall size of the sensor may be reduced.

Also, since the plurality of magnetic cores 110 each formed to have a width smaller than a length and a height thereof are used, demagnetization of the magnetic cores 110 with respect to the magnetic fields in the length direction (the x-axis direction) and the height direction (the z-axis direction or the direction perpendicular to the x-y plane) may be reduced, improving sensitivity and efficiency of the sensor.

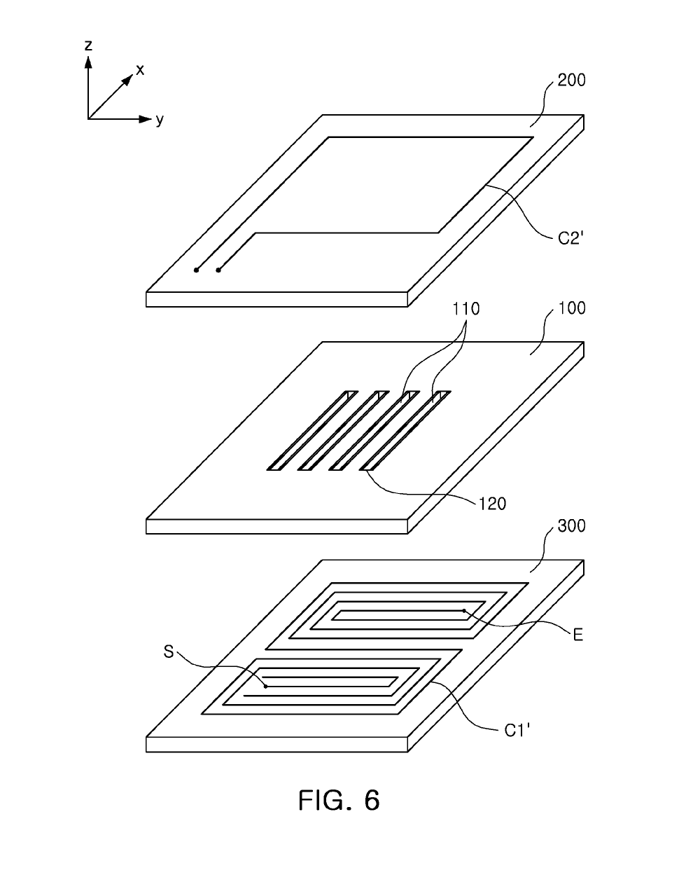

FIG. 6 is an exploded perspective view schematically illustrating an orthogonal fluxgate sensor according to a fourth exemplary embodiment of the present disclosure.

Referring to FIG. 6, the orthogonal fluxgate sensor according to the fourth exemplary embodiment of the present disclosure is identical to the orthogonal fluxgate sensor according to the third exemplary embodiment of the present disclosure as described above, except for first and second coils C1′ and C2′. Thus, descriptions thereof, excluding those of the first and second coils C1′ and C2′, will be omitted.

The first coil C1 may be provided in any one of the second and third substrates 200 and 300 stacked above and below the first substrate 100.

Also, the first coil C1′ may have a spiral shape with the parts of the first coil directly above or below the magnetic cores forming parallel lines.

The second coil C2′ may be provided in the other of the second and third substrates 200 and 300, and surround the plurality of magnetic cores 110 and the first coil C1′ on the x-y plane on the plane on which the plurality of magnetic cores 110 are formed.

In the present exemplary embodiment, it is described that the first coil C1′ is provided in any one of the second and third substrates 300 and the second coil C2′ is formed in the other, but the present disclosure is not limited thereto and both the first and second coils C1′ and C2′ may be provided in any one of the second and third substrates 200 and 300.

In such a case, the orthogonal fluxgate sensor according to the fourth exemplary embodiment of the present disclosure may include the first substrate 100 having the plurality of magnetic cores 110 formed therein and the second substrate 200 (or the third substrate 300) stacked above or below the first substrate 100 and having the first and second coils C1′ and C2′ formed therein.

The first coil C1′ may be formed by connecting the outermost coil strands of two coils wound in the same direction.

Also, the first coil C1′ may be spread, while being wound in one direction, and be rewound in the opposite direction.

In other words, the first coil C1′ may have a dual-spiral structure.

Thus, when it is assumed that a current flows from a start point S to an end point E of the first coil C1′, in an inner portion of the first coil C1′, the current flows in the same direction.

Here, the plurality of magnetic cores 110 may be positioned within the region of the first coil C1′ in which the current flows in the same direction.

Also, the plurality of magnetic cores 110 may be positioned between the start point S and the endpoint E of the first coil C1′.

Thus, a magnetic field may be applied to the entirety of the plurality of magnetic cores 110 in a predetermined direction by the first coil C1′.

As set forth above, the orthogonal fluxgate sensor according to exemplary embodiments of the present disclosure may have a significantly reduced overall height, while measuring a magnetic field in a direction perpendicular to a plane on which the sensor is formed.

Also, since two coils alternately serve as a magnetic field generating coil and a detecting coil, the orthogonal fluxgate sensor may have a simple structure and be miniaturized.

While exemplary embodiments have been shown and described above, it will be apparent to those skilled in the art that modifications and variations could be made without departing from the spirit and scope of the present disclosure as defined by the appended claims.

What is claimed is:

1. An orthogonal fluxgate sensor, comprising:
a plurality of magnetic cores provided in a length direction;
a first coil enclosing the plurality of magnetic cores in a solenoid form; and
a second coil surrounding the plurality of magnetic cores and the first coil,
wherein when an alternating current (AC) power source is connected to the first coil, an AC voltmeter is connected to the second coil, and when the AC power source is connected to the second coil, the AC voltmeter is connected to the first coil.

2. The orthogonal fluxgate sensor of claim 1, wherein each of the magnetic cores is formed to be narrow in a width direction thereof, relative to length and height directions thereof.

3. The orthogonal fluxgate sensor of claim 1, wherein each of the magnetic cores has lower demagnetizing field over magnetic fields in the length and height directions thereof than those over a magnetic field in the width direction thereof.

4. The orthogonal fluxgate sensor of claim 1, wherein the second coil surrounds the plurality of magnetic cores and the first coil at least once in a spiral manner.

5. Thee orthogonal fluxgate sensor of claim 1, wherein each of the magnetic cores is disposed to slope in the width direction thereof based on the height direction thereof.

6. The orthogonal fluxgate sensor of claim 5, wherein each of the magnetic cores slops in a direction opposite to the direction in which an adjacent magnetic core slopes.

7. An orthogonal fluxgate sensor, comprising:
a plurality of magnetic cores provided in a length direction;
a first coil disposed above or below the plurality of magnetic cores and having a spiral shape with the parts of the first coil directly above or below the magnetic cores forming parallel lines; and
a second coil surrounding the plurality of magnetic cores and the first coil,
wherein when an alternating current (AC) power source is connected to the first coil, an AC voltmeter is connected to the second coil, and when the AC power source is connected to the second coil, the AC voltmeter is connected to the first coil.

8. The orthogonal fluxgate sensor of claim 7, wherein each of the magnetic cores is formed to be narrow in a width direction thereof, relative to length and height directions thereof.

9. The orthogonal fluxgate sensor of claim 7, wherein each of the magnetic cores has lower demagnetizing field over magnetic fields in the length and height directions thereof than those over a magnetic field in the width direction thereof.

10. The orthogonal fluxgate sensor of claim 7, wherein each of the magnetic cores is disposed to slope in the width direction thereof based on the height direction thereof.

11. The orthogonal fluxgate sensor of claim 10, wherein each of the magnetic cores slopes in a direction opposite to the direction in which an adjacent magnetic core slopes.

12. An orthogonal fluxgate sensor, comprising:
a first substrate having a plurality of magnetic cores formed therein; and
second and third substrates stacked above and below the first substrate,
wherein a first coil is formed in the second and third substrates to enclose the plurality of magnetic cores in a solenoid form, a second coil is formed in the second or third substrate to surround the plurality of magnetic cores and the first coil, and when an alternating current (AC) power source is connected to the first coil, an AC voltmeter is connected to the second coil, and when the AC power source is connected to the second coil, the AC voltmeter is connected to the first coil.

13. The orthogonal fluxgate sensor of claim 12, wherein a plurality of through holes penetrating through the first substrate in a rectangular shape are formed in the first substrate, and magnetic thin films are provided on inner walls of the respective through holes to form the plurality of magnetic cores.

14. The orthogonal fluxgate sensor of claim 13, wherein each of the magnetic cores has lower demagnetizing field over magnetic fields in the length and height directions thereof than those over a magnetic field in the width direction thereof.

15. The orthogonal fluxgate sensor of claim 12, wherein the second coil surrounds the plurality of magnetic cores and the first coil at least once in a spiral manner.

16. The orthogonal fluxgate sensor of claim 12, wherein the second and third substrates have conductive patterns formed therein, and the first through third substrates have via holes to allow end portions of the respective conductive patterns to be connected therethrough to form the first coil in a solenoid form.

17. An orthogonal fluxgate sensor, comprising:
a first substrate having a plurality of magnetic cores formed therein; and
second and third substrates stacked above and below the first substrate,
wherein a first coil is formed in any one of the second and third substrates having a spiral shape with the parts of the first coil directly above or below the magnetic cores forming parallel lines; a second coil is formed in the other of the second and third substrate to surround the plurality of magnetic cores and the first coil, and when an alternating current (AC) power source is connected to the first coil, an AC voltmeter is connected to the second coil, and when the AC power source is connected to the second coil, the AC voltmeter is connected to the first coil.

18. The orthogonal fluxgate sensor of claim 17, wherein a plurality of through holes penetrating through the first substrate in a rectangular shape are formed in the first substrate, and magnetic thin films are provided on inner walls of the respective through holes to form the plurality of magnetic cores.

19. The orthogonal fluxgate sensor of claim 18, wherein each of the magnetic cores has lower demagnetizing field over magnetic fields in the length and height directions thereof than those over a magnetic field in the width direction thereof.

20. The orthogonal fluxgate sensor of claim 17, wherein the magnetic cores are positioned within a region of the first coil in which a current flows in the same direction.
